(19) United States
(12) Patent Application Publication
(10) Pub. No.: US 2024/0324112 A1
(43) Pub. Date: Sep. 26, 2024

(54) SEMICONDUCTOR STORAGE DEVICE

(71) Applicant: Kioxia Corporation, Tokyo (JP)

(72) Inventor: Takuya OKISHIMA, Yokohama Kanagawa (JP)

(73) Assignee: Kioxia Corporation, Tokyo (JP)

(21) Appl. No.: 18/590,266

(22) Filed: Feb. 28, 2024

(30) Foreign Application Priority Data
Mar. 20, 2023 (JP) 2023-043821

(51) Int. Cl. H05K 5/00; H01L 25/065

(52) U.S. Cl. CPC H05K 5/0026; H01L 25/0657; H01L 2225/0651; H01L 2225/06562; H01L 2225/06586

(57) ABSTRACT

A semiconductor storage device includes a circuit board having a first surface and a second surface opposite to each other; an electronic component disposed on the first surface of the circuit board; a plurality of conductive members disposed on the second surface of the circuit board and electrically coupled to the circuit board, wherein the conductive members each include a conductive material; and an information display region provided on the second surface of the circuit board. The information display region has an information display pattern formed of a coating material or the conductive material of the conductive members.

### CROSS-REFERENCE TO RELATED APPLICATION(S)

This application is based upon and claims the benefit of priority from Japanese Patent Application No. 2023-043821, filed Mar. 20, 2023, the entire contents of which are incorporated herein by reference.

### FIELD

Embodiments described herein relate generally to a semiconductor storage device.

### BACKGROUND

A semiconductor storage device including a substrate and an electronic component mounted on the substrate is known. The semiconductor storage device has a mark such as a two-dimensional code. Such a mark is, for example, management information such as manufacturing history information.

### DESCRIPTION OF THE DRAWINGS

FIG. 1 is a perspective view showing a storage device according to a first embodiment.

FIG. 2 is a perspective view showing a storage device according to the first embodiment in a partially disassembled manner.

FIG. 3 is a cross-sectional view showing a configuration of a NAND memory according to the first embodiment.

FIG. 4 is a bottom view showing a configuration of the NAND memory according to the first embodiment.

FIG. 5 is a plan view showing an information display pattern according to the first embodiment.

FIG. 6A is a view showing a method of manufacturing the NAND memory according to the first embodiment, and is a plan view showing a large circuit board.

FIG. 6B is a view showing a method of manufacturing the NAND memory according to the first embodiment, and is a plan view showing a modification example of the large circuit board.

FIG. 7 is a diagram showing a method of manufacturing the NAND memory according to the first embodiment, and is a cross-sectional view showing a part of a large circuit board.

FIG. 8 is a diagram showing a method of manufacturing the NAND memory according to the first embodiment, and is a cross-sectional view showing a part of a large circuit board.

FIG. 9 is a diagram showing a method of manufacturing the NAND memory according to the first embodiment, and is a cross-sectional view showing a part of a large circuit board.

FIG. 10 is a diagram showing a method of manufacturing the NAND memory according to the first embodiment, and is a cross-sectional view showing a part of a large circuit board.

FIG. 11 is a diagram showing a method of manufacturing the NAND memory according to the first embodiment, and is a cross-sectional view showing a part of a large circuit board.

FIG. 12A is a diagram showing a method of manufacturing the NAND memory according to the first embodiment, and is a cross-sectional view showing a device used when solder balls are disposed on a land.

FIG. 12B is a diagram showing a method of manufacturing the NAND memory according to the first embodiment, and is a cross-sectional view showing a device used when solder balls are disposed on a land.

FIG. 13 is a plan view showing an information display pattern according to a second embodiment.

FIG. 14 is a bottom view showing a configuration of a modification example of the NAND memory according to the second embodiment.

FIG. 15 is a bottom view showing a configuration of a modification example of the NAND memory according to the second embodiment.

FIG. 16 is a bottom view showing a configuration of a modification example of the NAND memory according to the second embodiment.

FIG. 17 is a bottom view showing a configuration of a modification example of the NAND memory according to the second embodiment.

### DETAILED DESCRIPTION

Embodiments provide a semiconductor storage device capable of improving a degree of freedom in design.

In general, according to one embodiment, the semiconductor storage device includes a circuit board having a first surface and a second surface opposite to each other; an electronic component disposed on the first surface of the circuit board; a plurality of conductive members disposed on the second surface of the circuit board and electrically coupled to the circuit board, wherein the conductive members each include a conductive material; and an information display region provided on the second surface of the circuit board. The information display region has an information display pattern formed of a coating material or the conductive material of the conductive members.

Hereinafter, the semiconductor storage device according to the embodiment will be described with reference to the drawings. In the following description, configurations having the same or similar functions are designated by the same reference numerals. Then, the duplicate description of those configurations may be omitted.

In the present application, ordinal numbers such as “first”, “second”, and “third” may be used. The ordinal number does not indicate the number of members described by the ordinal number.

In the present application, the terms “parallel”, “perpendicular”, or “same” may include “substantially parallel”, “substantially perpendicular”, or “substantially the same”, respectively.

In the present application, the term “connection” is not limited to mechanical connection, and may include electrical connection. In addition, “connection” is not limited to a case where two elements that are connection targets are directly connected, but may also include a case where two elements that are connection targets are connected to another element interposed therebetween. In addition, the phrase “connection” is not limited to a case where the components are connected to each other, and may also include a case where the components are only in contact with each other.

In the present application, the term “overlapping” may include a case where two elements overlap with another element interposed therebetween.

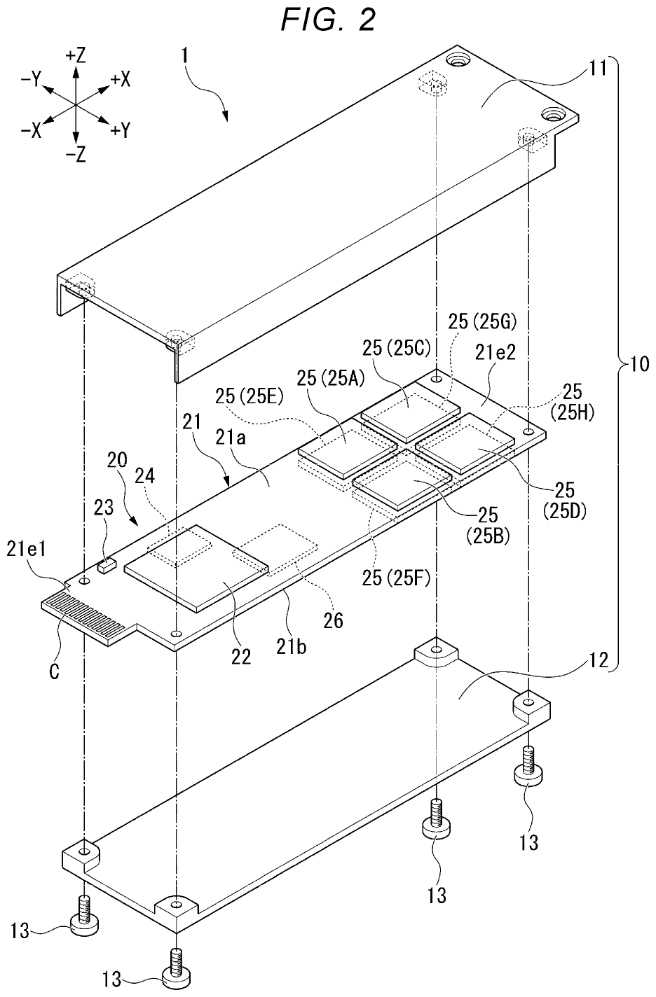

Here, the +X direction, −X direction, +Y direction, −Y direction, +Z direction, and −Z direction will be defined. The +X direction, the −X direction, the +Y direction, and the −Y direction are directions parallel to a first surface 21a of a substrate 21 described later (see FIG. 2).

The +X direction is a direction from a first end portion 21e1 of the substrate 21 toward a second end portion 21e2 (see FIG. 2). The −X direction is a direction opposite to the +X direction. When the +X direction and the −X direction are not distinguished, they are simply referred to as an “X direction”. The +Y direction and the −Y direction are directions that intersect (for example, are perpendicular to) the X direction. The X direction is an example of a “first direction”.

The +Y direction is a direction from a NAND memory 25A to a NAND memory 25B, which will be described later (refer to FIG. 2). The −Y direction is a direction opposite to the +Y direction. When the +Y direction and the −Y direction are not distinguished, both directions are simply referred to as a “Y direction”. The Y direction is a direction intersecting the X direction and is an example of a “second direction”.

The +Z direction and the −Z direction are directions that intersect (for example, are perpendicular to) the X direction and the Y direction. The +Z direction and the −Z direction are a thickness direction of the substrate 21. The +Z direction is a direction from the second surface 21b toward the first surface 21a of the substrate 21 (see FIG. 2). The −Z direction is a direction opposite to the +Z direction. When the +Z direction and the −Z direction are not distinguished, both directions are simply referred to as a “Z direction”.

### First Embodiment

### Overall Configuration of Storage Device

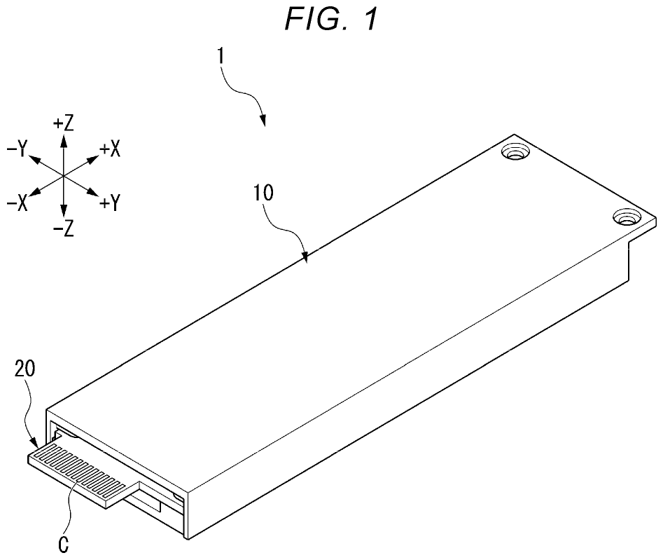

A storage device 1 according to the first embodiment will be described with reference to FIGS. 1 to 5.

FIG. 1 is a perspective view showing the storage device 1. The storage device 1 is, for example, a storage device such as a solid state drive (SSD). The storage device 1 is attached to, for example, an information processing device (hereinafter, referred to as a “host device”) such as a server or a personal computer. The storage device 1 is used as a storage region of the host device.

FIG. 2 is a perspective view showing a part of the storage device 1. The storage device 1 has, for example, a housing 10 and a substrate unit 20.

### Housing

The housing 10 is a member that forms an outline of the storage device 1 (see FIG. 1). The shape of the housing 10 is, for example, a flat rectangular cylinder. As shown in FIG. 2, the housing 10 includes, for example, a first member 11, a second member 12, and a plurality of fixing members 13. The first member 11 includes, for example, a wall portion located on the +Z direction side with respect to the substrate unit 20, a wall portion located on the +Y direction side with respect to the substrate unit 20, and a wall portion located on the −Y direction side with respect to the substrate unit 20. The second member 12 includes a wall portion located on the −Z direction side with respect to the substrate unit 20. The fixing member 13 is a member that connects the first member 11 and the second member 12. The fixing member 13 is, for example, a screw. In the present embodiment, the housing 10 is formed by connecting the first member 11 and the second member 12 with the plurality of fixing members 13.

### Substrate Unit

The substrate unit 20 is an assembly on which a component including a circuit is disposed. The substrate unit 20 is accommodated in the housing 10 at least in part. The substrate unit 20 has, for example, a substrate 21, a controller 22, a power conversion component 23, a power supply circuit component 24, a plurality of NAND memory chips 25 (NAND memory chips 25A to 25H), and a dynamic random access memory (DRAM) 26.

The substrate 21 is a printed wiring board. The substrate 21 is a plate-like member extending in the X direction and the Y direction. The substrate 21 has the first surface 21a and the second surface 21b. The first surface 21a is a surface that faces the +Z direction. The second surface 21b is located on a side opposite to the first surface 21a. The second surface 21b is a surface that faces the −Z direction side.

The substrate 21 has a first end portion 21e1 and a second end portion 21e2 located on a side opposite to the first end portion 21e1 as both end portions in a longitudinal direction of the substrate 21. The first end portion 21e1 of the substrate 21 has a connector C. The connector C is an electrical connection portion that can be connected to the host device.

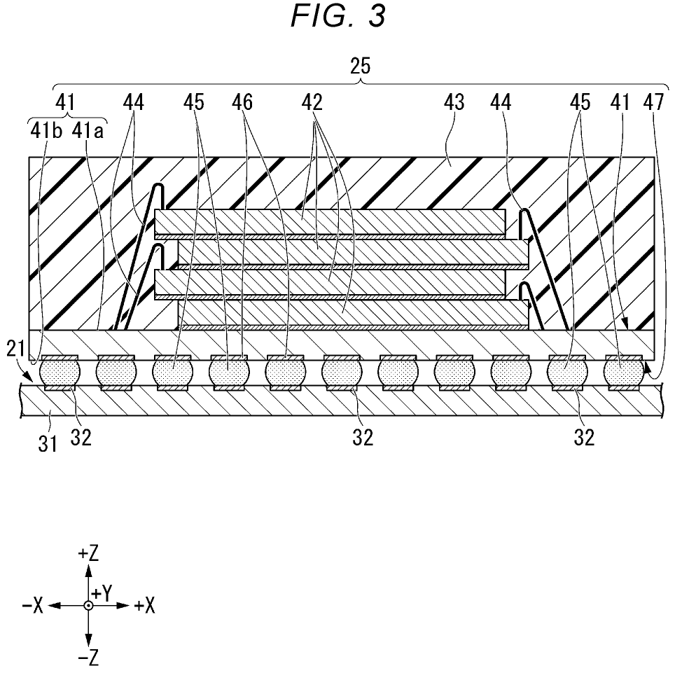

The substrate 21 includes an insulating base material 31 and a plurality of pads 32 provided on the insulating base material 31 (see FIG. 3). The plurality of pads 32 are portions electrically connected to the electrical connection terminals to be described later.

### Controller

The controller 22 is a control component disposed on the substrate 21. The controller 22 centrally controls the entire storage device 1. The controller 22 includes, for example, a system on a chip (SoC) in which a host interface circuit that performs communication with a host device, a control circuit that controls the plurality of NAND memory chips 25, a control circuit that controls the DRAM 26, and the like are integrated into one semiconductor chip. The controller 22 can control writing, reading, or erasing of data for the plurality of NAND memory chips 25.

### Electricity Conversion Component

The power conversion component 23 is a component that converts power. The power conversion component 23 is, for example, a DC-DC converter. The power conversion component 23 converts the power supplied from the host device through the connector C into desired power. The power conversion component 23 outputs the converted power to the power supply circuit component 24.

### Power Supply Circuit Component

The power supply circuit component 24 is a component that performs power management. The power supply circuit component 24 is, for example, a power management IC (PMIC). The power supply circuit component 24 supplies power to each component (the controller 22, the NAND memory 25, the DRAM 26, and the like) provided in the substrate unit 20.

### DRAM

The DRAM 26 is a semiconductor package that includes semiconductor memory chips storing data in a volatile manner. The DRAM 26 is an example of a “semiconductor storage device”.

The DRAM 26 may be used as a data buffer that temporarily stores write data, which is received from the host device, or read data, which is read from one or more of the NAND memory chips 25, or the like.

NAND memory

The NAND memory 25 is a semiconductor package that includes semiconductor memory chips storing data in a nonvolatile manner. The NAND memory 25 is, for example, a NAND flash memory. In other words, the NAND memory 25 is an example of a “semiconductor memory” and an example of a “semiconductor storage device”.

As shown in FIG. 2, the plurality of NAND memory chips 25 are actually mounted on the first surface 21a and the second surface 21b of the substrate 21. Meanwhile, the “semiconductor memory” may be another type of memory such as a NOR-type memory, a magnetoresistive random access memory (MRAM), or a resistive change memory.

The plurality of NAND memory chips 25 are disposed on the +X direction side with respect to the controller 22. The plurality of NAND memory chips 25 include a plurality (for example, four) of NAND memory chips 25A to 25D mounted on the first surface 21a of the substrate 21 and a plurality (for example, four) of NAND memory chips 25E to 25H mounted on the second surface 21b of the substrate 21.

The NAND memory chips 25A and 25B are disposed on the −X direction side with respect to the NAND memory chips 25C and 25D. The NAND memory chips 25A and 25B are adjacent to each other in the Y direction. The NAND memory chips 25C and 25D are adjacent to each other in the Y direction.

Similarly, the NAND memory chips 25E and 25F are disposed on the −X direction side with respect to the NAND memory chips 25G and 25H. The NAND memory chips 25E and 25F are adjacent to each other in the Y direction. The NAND memory chips 25G and 25H are adjacent to each other in the Y direction. Hereinafter, when the NAND memory chips 25A to 25H are not distinguished from each other, the NAND memory chips 25A to 25H are simply referred to as “NAND memory 25”.

### Configuration of NAND Memory

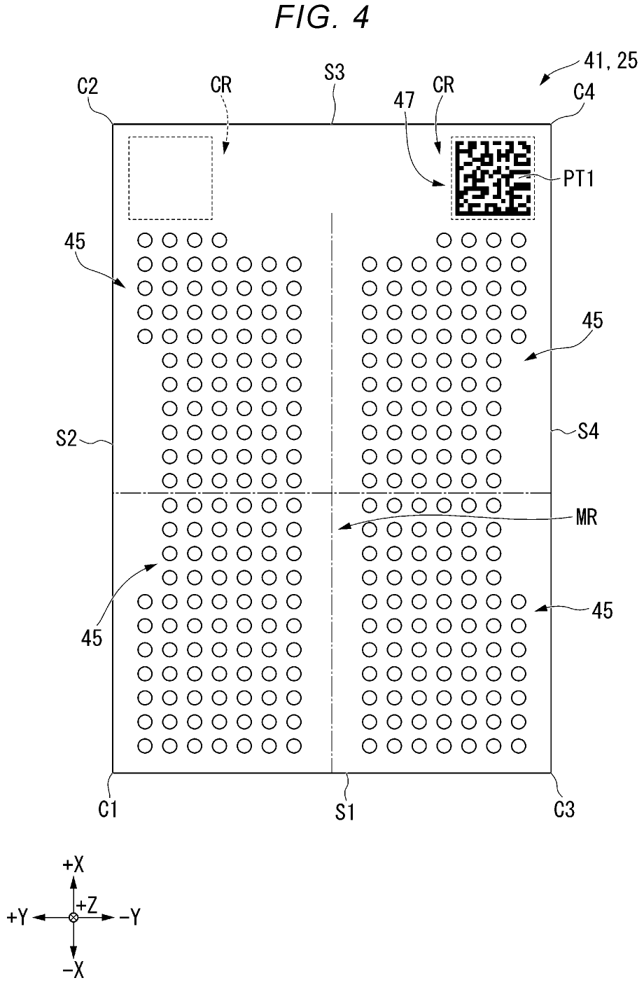

Next, a configuration of the NAND memory 25 will be described with reference to FIGS. 3 and 4.

FIG. 3 is a cross-sectional view showing the configuration of the NAND memory 25.

FIG. 4 is a bottom view showing the configuration of the NAND memory 25. FIG. 4 may also be referred to as a plan view of the circuit board 41 as viewed in the +Z direction.

As shown in FIG. 3, the NAND memory 25 has the circuit board 41, one or more semiconductor memory chips 42, a sealing resin portion 43, a plurality of bonding wires 44, a plurality of conductive members 45, a plurality of lands 46, and an information display region 47.

### Circuit Board

The circuit board 41 is a substrate serving as a base of the NAND memory 25. The circuit board 41 is a printed wiring board. The circuit board 41 is a plate-like member extending in the X direction and the Y direction. The circuit board 41 includes a first surface 41a and a second surface 41b that is located on a side opposite to the first surface 41a. When the circuit board 41 is viewed in the Z direction, the circuit board 41 defines the outer shape of the NAND memory 25. The second surface 41b faces the insulating base material 31. The second surface 41b is parallel to the X direction and the Y direction.

As shown in FIG. 4, when the circuit board 41 is viewed in the Z direction, the shape of the circuit board 41 configuring the NAND memory 25 is a rectangle. The circuit board 41 has four side portions S1 to S4, four corner portions C1 to C4, a central region MR, and a corner region CR.

The side portion S1 is, for example, a side portion located at an end of the NAND memory 25 on the −X direction side. The side portion S1 extends in the Y direction. The side portion S2 is, for example, a side portion located at an end of the NAND memory 25 on the +Y direction side. The side portion S2 extends in the X direction. The side portion S3 is, for example, a side portion located at an end of the NAND memory 25 on the +X direction side. The side portion S3 extends in the Y direction. The side portion S4 is, for example, a side portion located at an end of the NAND memory 25 on the −Y direction side. The side portion S4 extends in the X direction.

The side portion S1 is located between the two corner portions C1 and C3 adjacent to each other. The side portion S2 is located between the two corner portions C1 and C2 adjacent to each other. The side portion S3 is located between the two corner portions C2 and C4 adjacent to each other. The side portion S4 is located between the two corner portions C3 and C4 adjacent to each other.

The corner portion C1 is an intersection between the side portion S1 and the side portion S2. The corner portion C2 is an intersection between the side portion S2 and the side portion S3. The corner portion C3 is an intersection between the side portion S1 and the side portion S4. The corner portion C4 is an intersection between the side portion S3 and the side portion S4.

The central region MR is located at the center in the X direction and the Y direction.

The corner region CR is located near one corner portion of the plurality of corner portions C1 to C4 with respect to the central region MR. In the present embodiment, the corner region CR is located near the corner portion C4.

### Semiconductor Memory Chip

Each of the one or more semiconductor memory chips 42 has a plurality of memory cells. The semiconductor memory chip 42 is a component capable of storing data. The semiconductor memory chip 42 is an example of an “electronic component”. The one or more semiconductor memory chips 42 are mounted on the first surface 41a of the circuit board 41. The one or more semiconductor memory chips 42 are stacked in the Z direction on the first surface 41a of the circuit board 41.

Each of the one or more semiconductor memory chips 42 is a plate-like member along the X direction and the Y direction. A structure formed by stacking one or more semiconductor memory chips 42 may be referred to as a stack.

### Sealing Resin Portion

The sealing resin portion 43 is a sealing portion that covers one or more semiconductor memory chips 42 and the plurality of bonding wires 44. The sealing resin portion 43 has insulating properties. The sealing resin portion 43 may be referred to as a mold resin portion.

### Bonding Wire

The bonding wire 44 electrically connects the semiconductor memory chip 42 and the circuit board 41.

### Conductive Member

Each of the plurality of conductive members 45 is exposed to the outside of the NAND memory 25. Specifically, the plurality of conductive members 45 are provided on the second surface 41b of the circuit board 41. The plurality of conductive members 45 are disposed on the second surface 41b of the circuit board 41. The plurality of conductive members 45 are electrically connected to the circuit board 41. The plurality of conductive members 45 are formed of a conductive material.

Each of the plurality of conductive members 45 is an electrical connection terminal exposed from the second surface 41b. The plurality of conductive members 45 are disposed side by side in the X direction and the Y direction. Each of the plurality of conductive members 45 is bonded to the pad 32 of the insulating base material 31.

The plurality of conductive members 45 are solder. In the present embodiment, the plurality of conductive members 45 have a shape in which the solder balls are deformed by mounting the NAND memory 25 on the substrate 21.

In the present embodiment, the NAND memory 25 is a ball grid array (BGA) type semiconductor package.

### Land

The plurality of lands 46 are provided on the second surface 41b of the circuit board 41. The plurality of lands 46 are sites electrically connected to the plurality of conductive members 45 in a one-to-one manner. The plurality of lands 46 constitute a part of the wiring layer formed on the circuit board 41. The wiring layer is formed of copper. Therefore, the plurality of lands 46 are also formed of copper.

In the second surface 41b of the circuit board 41, a solder resist is provided in a region where the plurality of lands 46 are not formed. The solder resist is an insulating layer that covers the electrode layer formed on the circuit board 41 and protects the electrode layer. The solder resist has a plurality of openings. The positions of the plurality of openings of the solder resist correspond to the positions of the plurality of lands 46. In other words, the electrode layer exposed through the opening of the solder resist is the land 46.

### Information Display Region

As shown in FIG. 4, the information display region 47 is provided on the second surface 41b of the circuit board 41. In the present embodiment, the information display region 47 is located in the corner region CR. In other words, the information display region 47 is located near the corner portion C4. In the present embodiment, the information display region 47 is provided at a position different from a position of the plurality of conductive members 45.

The information display region 47 has an information display pattern PT1 formed of a coating material.

### Modification Example 1 of Information Display Region

The position of the information display region 47 is not limited to the example shown in FIG. 4.

For example, the corner region CR may be located near the corner portion C2, which is one corner portion of the four corner portions C1 to C4. In other words, the corner region CR may be located closer to the corner portion C2 with respect to the central region MR. In this case, the information display region 47 is positioned near the corner portion C2 (corner region CR indicated by the dotted line in FIG. 4).

### Modification Example 2 of Information Display Region

The number of information display regions 47 is not limited to the example shown in FIG. 4.

A configuration in which the information display region 47 is provided in the corner region CR located near the corner portion C2 and the information display region 47 is provided in the corner region CR located near the corner portion C4 may be adopted. In this case, the number of information display regions 47 is 2. Each of the two information display regions 47 has the information display pattern PT1. In addition, each of the two information display regions 47 may be provided with an information display pattern including information in which the amount of information is reduced to ½ with respect to the amount of the information display pattern PT1.

### Modification Example 3 of Information Display Region

In addition to the configuration of the information display region of Modification Example 2, the corner region CR may be provided near the corner portions C1 and C3.

Specifically, the corner region CR is located closer to each of the four corner portions C1 to C4 with respect to the central region MR. The number of the corner regions CR is 4. The information display region 47 is provided in each of the four corner regions CR. Each of the four information display regions 47 has the information display pattern PT1. In addition, each of the four information display regions 47 may be provided with an information display pattern including information in which the amount of information is reduced to ¼ with respect to the amount of the information display pattern PT1.

In the example shown in FIG. 4 and Modification Examples 1 to 3 of the information display region, each of the four corner portions C1 to C4 may be referred to as a first corner portion, a second corner portion, a third corner portion, and a fourth corner portion.

Each of the four corner regions CR located closer to the four corner portions C1 to C4 with respect to the central region MR may be referred to as a first corner region, a second corner region, a third corner region, and a fourth corner region.

Each of the information display regions located in a first corner region, a second corner region, a third corner region, and a fourth corner region may be referred to as a first information display region, a second information display region, a third information display region, and a fourth information display region.

Each of the information display patterns provided in the first information display region, the second information display region, the third information display region, and the fourth information display region may be referred to as a first information display pattern, a second information display pattern, a third information display pattern, and a fourth information display pattern.

### Information Display Pattern

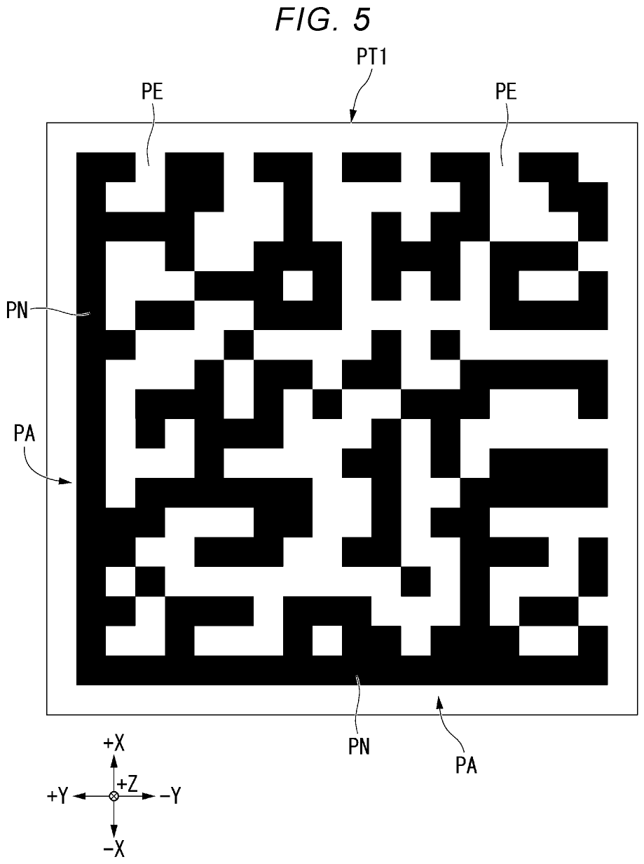

FIG. 5 shows an example of the information display pattern PT1.

The information display pattern PT1 is, for example, a known two-dimensional code. The information display pattern PT1 is a code of a display method having information in the Y direction and the X direction.

In the present embodiment, the coating material is applied to the corner region CR of the second surface 41b using a known printing method. Accordingly, the information display pattern PT1 is formed in the corner region CR. That is, the information display pattern PT1 according to the first embodiment is formed of the coating material.

The information display pattern PT1 includes a plurality of first portions PE in which the coating material is present and a plurality of second portions PN in which the coating material is not present.

The information display pattern PT1 has a plurality of information display rows PA represented by a combination of the plurality of first portions PE and the plurality of second portions PN. A plurality of information display rows PA are arranged in the X direction and the Y direction intersecting the X direction.

The information display pattern PT1 is 18×18 two-dimensional information.

The information indicated by the information display pattern PT1 in this way is management information such as manufacturing history information regarding the NAND memory 25 to which the information display pattern PT1 is attached.

Specifically, the two-dimensional code includes, for example, 18-digit information. Examples of the 18-digit information included in the two-dimensional code include the following information.
Date and time of manufacturing NAND memory 25
Type of manufacturing apparatus used in manufacturing process of NAND memory 25
Lot number in manufacturing process of NAND memory 25

For example, it is considered that failure occurs in the NAND memory 25 after the shipment of the NAND memory 25. In this case, the NAND memory 25 in which the failure has occurred is collected, and the two-dimensional code attached to the NAND memory 25 is referred to. Accordingly, it is possible to obtain the management information of the NAND memory 25 in which the failure has occurred. Based on the obtained information, it is possible to perform a failure analysis such as a cause of failure.

### Method of Manufacturing NAND Memory

Next, a method of manufacturing the NAND memory 25 will be described.

The manufacturing method of the NAND memory 25 has the following steps 1 to 9.
(Step 1) Preprocessing Step of Semiconductor Wafer
(Step 2) Dicing of Semiconductor Wafer
(Step 3) Mounting of Semiconductor Memory Chip on Large Circuit Board
(Step 4) Wire Bonding between Large Circuit Board and Semiconductor Memory Chip
(Step 5) Coating of Resin Material on Large Circuit Board
(Step 6) Formation of Information Display Pattern on Large Circuit Board
(Step 7) Disposition of Solder Balls on Large Circuit Board
(Step 8) Reflow Treatment on Large Circuit Board
(Step 9) Dicing of Large Circuit Board

Next, the above steps 1 to 9 will be described in order.

In each of the steps 1 to 9, a modification example may be described.

### Step 1: Preprocessing Step of Semiconductor Wafer

The pretreatment step in the semiconductor wafer is, for example, a thermal oxidation step, a photoresist application step, an exposure step (patterning step), an etching step, an oxidation diffusion step, a film forming step, an ion implantation step, a flattening step, an inspection step, and the like.

### Step 2: Dicing of Semiconductor Wafer

The semiconductor wafer on which the pretreatment step has been completed is diced. As a result, a plurality of semiconductor memory chips 42 can be obtained from the semiconductor wafer.

### Step 3: Mounting of Semiconductor Memory Chip on Large Circuit Board

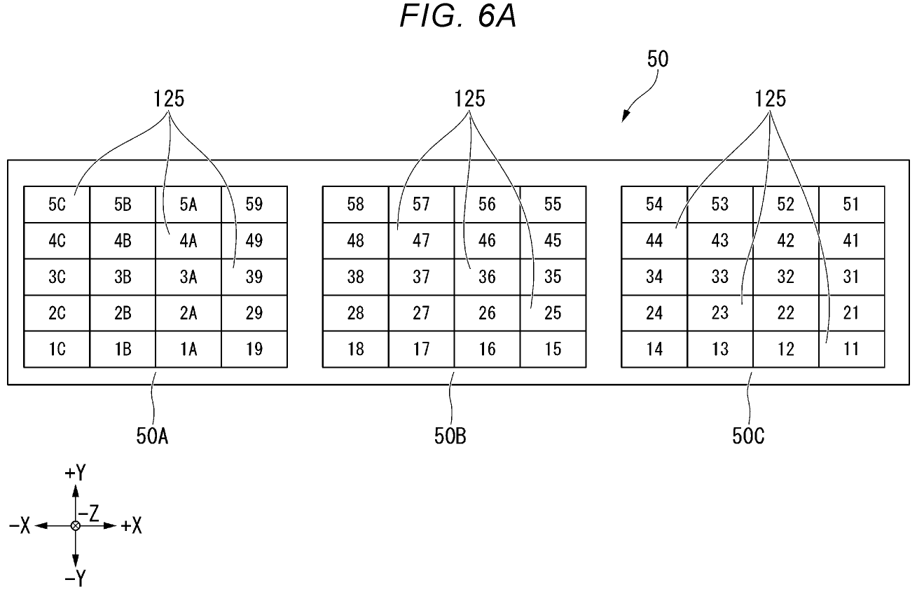

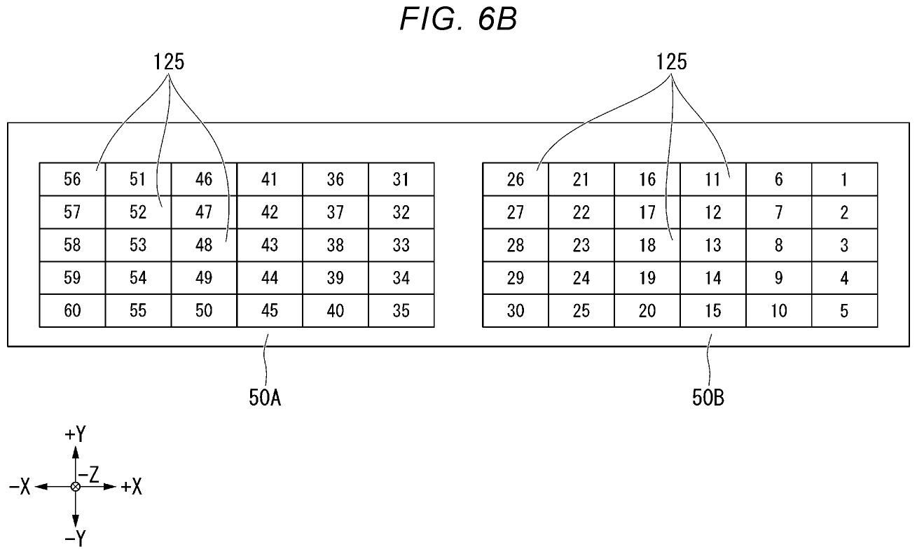

FIG. 6A is a plan view showing the large circuit board 50.

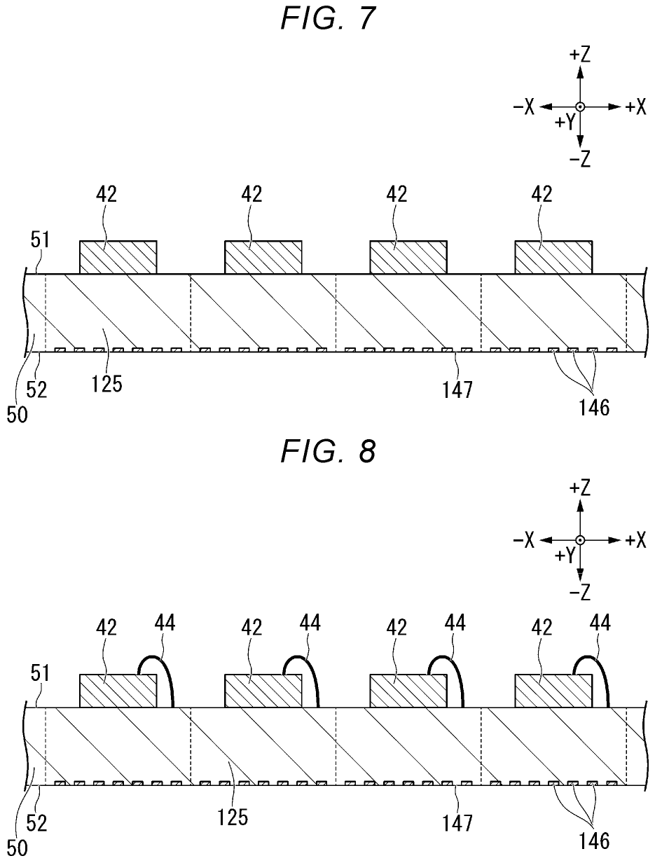

FIG. 7 is a cross-sectional view showing a part of the large circuit board 50. FIG. 7 is a diagram showing a step of providing a plurality of semiconductor memory chips 42 on the large circuit board 50.

In the large circuit board 50, a plurality of device regions 125 are assigned.

In the example shown in FIG. 6A, the large circuit board 50 has three region groups 50A, 50B, and 50C. Each of the three region groups 50A, 50B, and 50C has a plurality of device regions 125. In each region group, four device regions 125 are arranged in the X direction, and five device regions 125 are arranged in the Y direction. That is, the 4×5 device regions 125 are assigned to each region group. In this case, the size of each of the plurality of device regions 125 is, for example, 12 mm in the Y direction and 18 mm in the X direction.

Each of the plurality of device regions 125 has a wiring circuit that is independent of each other.

The device region 125 corresponds to the NAND memory 25 obtained by dicing the large circuit board 50 as will be described later.

In FIG. 7, a portion between the two device regions 125 adjacent to each other is indicated by a solid line. This portion is a portion that is cut by a cutter when the large circuit board 50 is diced.

As shown in FIG. 7, the large circuit board 50 has a first main surface 51 and a second main surface 52.

On the first main surface 51 of the large circuit board 50, the semiconductor memory chip 42 is mounted on each of the plurality of device regions 125.

As shown in FIG. 3, when the NAND memory 25 has a plurality of semiconductor memory chips 42, a stack in which a plurality of semiconductor memory chips 42 are stacked is prepared in advance, and the stack is mounted on each of the plurality of device regions 125.

A land 146 to be described later is formed on the second main surface 52.

In the second main surface 52 of the large circuit board 50, a solder resist is provided in a region where the plurality of lands 146 are not formed. The solder resist has a plurality of openings. In other words, the plurality of openings of the solder resist correspond to the plurality of lands 146.

### Modification Example of Step 3

The configuration of the large circuit board 50 is not limited to the example shown in FIG. 6A.

For example, the large circuit board 50 may have two region groups 50A and 50B shown in FIG. 6B. Each of the two region groups 50A and 50B has a plurality of device regions 125. In each region group, six device regions 125 are arranged in the X direction, and five device regions 125 are arranged in the Y direction. That is, the 6×5 device regions 125 are assigned to each region group. The device region 125 corresponds to the NAND memory 25 obtained by dicing the large circuit board 50 as will be described later.

Step 4: Wire Bonding between Large Circuit Board and Semiconductor Memory Chip

FIG. 8 is a cross-sectional view showing a part of the large circuit board 50. FIG. 8 is a diagram showing a step of wire bonding to the large circuit board 50 and the plurality of semiconductor memory chips 42.

The wire bonding is performed on the first main surface 51 of the large circuit board 50.

In each of the plurality of device regions 125, each of the plurality of device regions 125 and the semiconductor memory chip 42 are connected to each other by wire bonding with the bonding wire 44.

### Step 5: Coating of Resin Material on Large Circuit Board

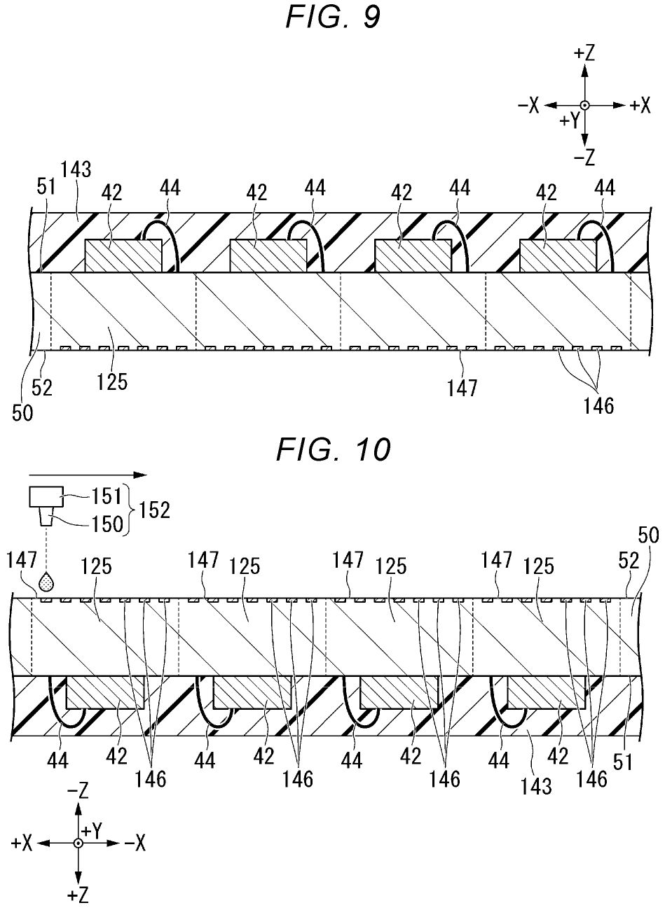

FIG. 9 is a cross-sectional view showing a part of the large circuit board 50. FIG. 9 is a view showing a step of applying a resin material to the first main surface 51 of the large circuit board 50.

The entire first main surface 51 of the large circuit board 50 is covered with the resin material 143 such that all of the plurality of device regions 125, the plurality of semiconductor memory chips 42, and the plurality of bonding wires 44 are covered. The resin material 143 is cured by a known method such as a drying step, a thermosetting step, or an ultraviolet curing step.

The distance from the first main surface 51 to the upper surface of the resin material 143, that is, the height of the resin material 143 in the Z direction on the first main surface 51 corresponds to the thickness of the sealing resin portion 43 of the NAND memory 25.

### Step 6: Formation of Information Display Pattern on Large Circuit Board

FIG. 10 is a cross-sectional view showing a part of the large circuit board 50. FIG. 10 is a view showing a step of coating the second main surface 52 of the large circuit board 50 with the coating material. The large circuit board 50 shown in FIG. 10 has a posture in which the posture of the large circuit board 50 shown in FIG. 9 is inverted in the Z direction.

On the second main surface 52 of the large circuit board 50, the information display pattern PT1 is formed in each of the information display regions 147 of the plurality of device regions 125 using a printing method.

The material used for forming the information display pattern PT1 is a coating material for forming the information display pattern PT1 by a known printing method. The coating material is, for example, an ink containing a pigment, a dye, a solvent, and the like.

In the present embodiment, the information display pattern PT1 is formed in the information display region 147 by using an inkjet method, which is one of the printing methods. Specifically, as shown in FIG. 10, a liquid droplet discharge device 152 having a discharge head 150 and a head moving mechanism 151 is used. The liquid droplet discharge device 152 discharges the ink from the discharge head 150 to the information display region 147 while the head moving mechanism 151 is moved in the X direction and the Y direction. As a result, the information display pattern PT1 is formed in the information display region 147. After the information display pattern PT1 is formed, a drying step may be performed as necessary.

The information display region 147 corresponds to the information display region 47 of the NAND memory 25 obtained by dicing the large circuit board 50.

### Modification Example 1 of Step 6

A printing method other than the inkjet method may be used as long as it is possible to form the two-dimensional code for the management information of each of the plurality of device regions 125, that is, each of the plurality of NAND memory chips 25.

For example, a printing method using an original plate may be adopted. In other words, a printing method using an original plate in which a printing pattern can be freely set may be adopted to correspond to the two-dimensional code for the management information. Such a printing method is not limited to the inkjet method, and a printing method such as a flexographic printing method, a screen printing method, a gravure printing method, or an offset printing method may be used. As the screen printing, silk printing may be adopted.

### Modification Example 2 of Step 6

The two-dimensional code having the same pattern as a pattern of the plurality of device regions 125 may be formed by a printing method using the same original plate. In this case, first, the two-dimensional code having the same pattern as the pattern of the plurality of device regions 125 is formed.

Thereafter, a part of the two-dimensional code of each of the plurality of device regions 125 is trimmed such that the two-dimensional codes of the plurality of device regions 125 are different from each other. By this trimming, the two-dimensional codes formed in the plurality of device regions 125 can be made different from each other. Therefore, the two-dimensional code for the management information can be formed in each of the plurality of device regions 125, that is, in each of the plurality of NAND memory chips 25.

### Step 7: Disposition of Solder Balls on Large Circuit Board

FIG. 11 is a cross-sectional view showing a part of the large circuit board 50. FIG. 11 is a view for showing a step of disposing the solder balls 145 on the second main surface 52 of the large circuit board 50. The large circuit board 50 shown in FIG. 11 has the same posture as a posture of the large circuit board 50 shown in FIG. 10.

On the second main surface 52 of the large circuit board 50, a plurality of lands 146 are formed in each of the plurality of device regions 125. The land 146 is exposed from the second main surface 52. The land 146 corresponds to the land 46 of the NAND memory 25 obtained by dicing the large circuit board 50.

In step 7, specifically, the plurality of solder balls 145 are disposed on the plurality of lands 146 using the collet 160 and the solder base 161.

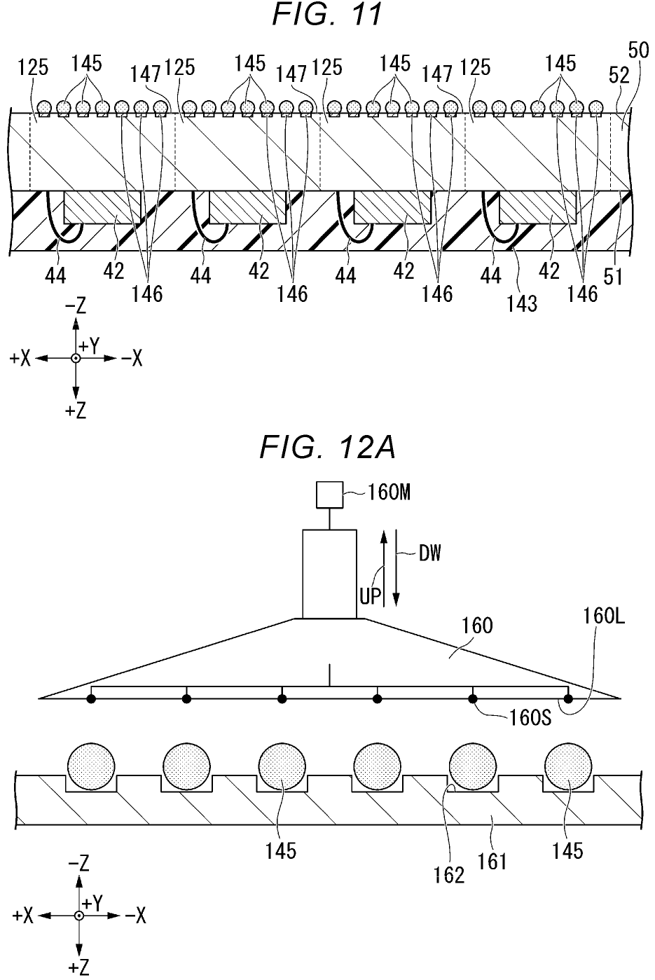

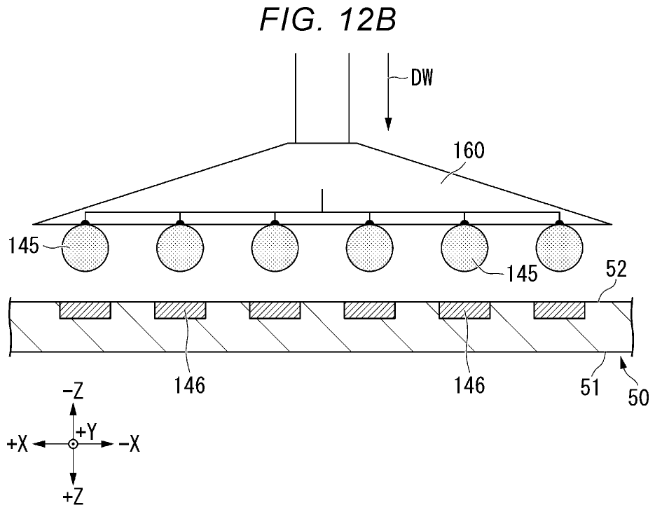

FIG. 12A and FIG. 12B are schematic sectional views showing a device used when the solder balls 145 are disposed on the lands 146.

FIG. 12A shows the collet 160 and the solder base 161.

The collet 160 has a vacuum drive unit 160M, a lower surface 160L, and a plurality of suction portions 160S. The plurality of suction portions 160S are open to the lower surface 160L. The plurality of suction portions 160S communicate with the vacuum drive unit 160M through a pipe provided inside the collet 160. The collet 160 is a rubber-like member that sucks up the plurality of solder balls 145 by vacuum suction.

The solder base 161 has a groove portion 162 in which the solder ball 145 is placed. The solder balls 145 are placed in advance in the groove portion 162 of the solder base 161.

The collet 160 is lowered in a direction DW, and the lower surface 160L of the collet 160 is brought into contact with the solder balls 145. At this time, the vacuum drive unit 160M of the collet 160 is driven. On the lower surface 160L of the collet 160, the plurality of solder balls 145 are sucked by a plurality of suction portions 160S one by one. Thereafter, the collet 160 is moved upward in a direction UP in a state where the collet 160 stores the plurality of solder balls 145, and the collet 160 is separated from the solder base 161.

Next, the collet 160 that stores the plurality of solder balls 145 is moved, and the collet 160 is caused to face the second main surface 52 of the large circuit board 50. The collet 160 is lowered in the direction DW, and the plurality of solder balls 145 held by the collet 160 are brought into contact with the plurality of lands 146 one by one. At this time, the driving of the vacuum drive unit 160M of the collet 160 is stopped. Accordingly, the suction state (storing state) between the collet 160 and the plurality of solder balls 145 is released. Accordingly, on the second main surface 52 of the large circuit board 50, the plurality of solder balls 145 are disposed on the plurality of lands 146 in each of the plurality of device regions 125.

In the present embodiment, step 6 of forming the information display pattern PT1 in the device region 125 is performed before step 7 of disposing the solder balls 145 in the device region 125. Accordingly, it is possible to prevent the ink from adhering to the solder ball 145. Therefore, it is possible to prevent electrical poor contact between the solder ball 145 and the land 146 due to the adhesion of the ink to the solder ball 145.

### Step 8: Reflow Treatment on Large Circuit Board

A reflow treatment (heating treatment) is performed on the large circuit board 50 using a known reflow furnace. The temperature of the reflow is, for example, about 240° C. As a result, a part of the solder balls 145 disposed on the lands 146 in each of the plurality of device regions 125 is melted. Accordingly, the solder ball 145 is set to the conductive member 45 and is bonded to the land 146. In other words, the conductive member 45 has a shape in which the solder ball 145 is deformed by the reflow treatment.

### Step 9: Dicing of Large Circuit Board

The large circuit board 50 is diced using a known dicing device to obtain the plurality of NAND memory chips 25. Each of the plurality of NAND memory chips 25 has a structure shown in FIGS. 3 and 4. Thereafter, the plurality of NAND memory chips 25 are subjected to processes such as testing, scanning, visual inspection, and baking, and are mounted on the insulating base material 31 of the substrate 21 described above.

According to the present embodiment, the information display region 47 can be formed on the second surface 41b of the circuit board 41 configuring the NAND memory 25. In addition, the information display pattern PT1 formed of the coating material can be formed in the information display region 47.

Here, the effects of the present embodiment will be described by comparing the present embodiment with a comparative example.

The semiconductor package of the comparative example has a configuration in which the semiconductor chip is covered with a sealing resin portion. A mark (information) which is management information is attached to the semiconductor package of the comparative example. A mark is provided on the semiconductor package of the comparative example by irradiating the surface of the sealing resin portion with laser light. In the semiconductor package of the comparative example, the semiconductor chip covered with the sealing resin portion may be damaged when the surface of the sealing resin portion is irradiated with the laser light.

In the semiconductor package of the comparative example, in order to avoid damage to the semiconductor chip, it is considered that only a specific region on the surface of the sealing resin portion is irradiated with the laser light such that the laser light irradiation position does not overlap the semiconductor chip.

However, when the area of the semiconductor chip is large, the area of a region where the laser light irradiation position and the semiconductor chip do not overlap decreases. Therefore, it is considered that a region for marking cannot be sufficiently secured on the surface of the sealing resin portion.

In addition, as another comparative example of the semiconductor package, a structure is also considered, in which the thickness of the sealing resin portion is increased and the semiconductor chip is protected, such that the semiconductor does not receive the influence of the light.

However, in this case, it is considered that the semiconductor package cannot be thinned as the thickness of the sealing resin portion increases.

Conversely, according to the present embodiment, it is not necessary to irradiate the surface of the sealing resin portion 43 with the laser light. Therefore, the semiconductor memory chip 42 is not damaged. As a result, the thickness of the sealing resin portion 43 can be reduced, and the thickness of the NAND memory 25 can be reduced.

Since the position of the information display pattern PT1 is not limited to the surface of the sealing resin portion 43, the degree of freedom in the design of the NAND memory 25 can be improved.

### Second Embodiment

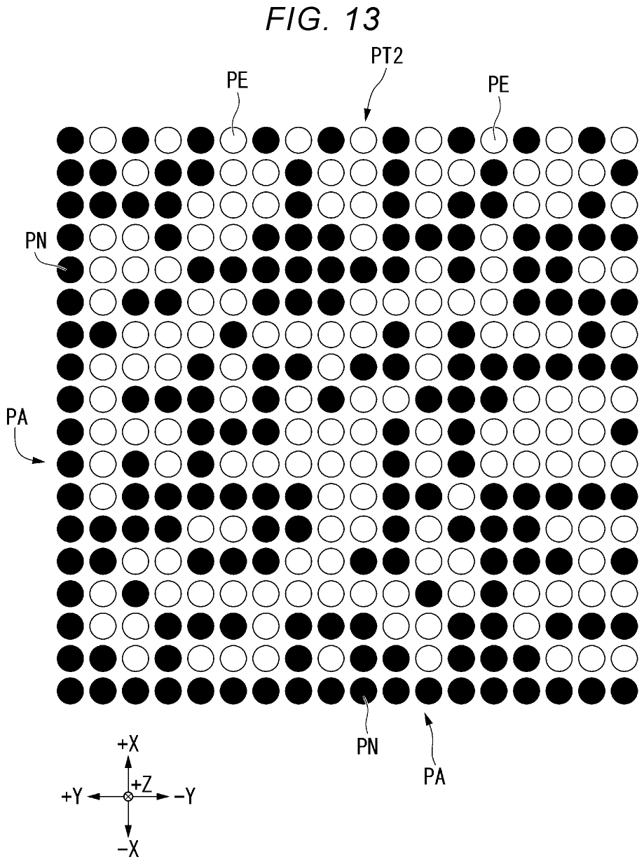

With reference to FIG. 13, a second embodiment will be described.

In the second embodiment, the same reference numerals are given to the same members as in the first embodiment, and the description thereof will be omitted or simplified. FIG. 13 shows an example of an information display pattern PT2 according to the second embodiment.

In the second embodiment, the information display pattern PT2 is provided, instead of the information display pattern PT1 provided in the information display region 47 shown in FIG. 4. That is, the information display region 47 of the second embodiment has the information display pattern PT2 formed of the same conductive material as the conductive material constituting the conductive member 45.

In the second embodiment, unlike the first embodiment, the plurality of lands 46 are provided in the information display region 47. The information display pattern PT2 is formed depending on whether the conductive material is disposed in each of the plurality of lands 46.

### Information Display Pattern

The information display pattern PT2 is, for example, a known two-dimensional code. The information display pattern PT2 is a code of a display method having information in the Y direction and the X direction.

The information display pattern PT2 is formed using a conductive material. The conductive material is solder. Specifically, in the present embodiment, the conductive material is disposed in the corner region CR of the second surface 41b by the step of disposing the solder balls described in the first embodiment and by the reflow process. Accordingly, the information display pattern PT2 is formed in the corner region CR.

That is, the information display pattern PT2 according to the second embodiment is formed of a conductive material. Similar to the information display pattern PT1, the information display pattern PT2 has management information regarding each of the plurality of manufactured NAND memory chips 25.

In FIG. 13, a white circular part and a black circular part are shown. The white circular portion indicates that the conductive material is mounted on the land 46. The black circular portion indicates that the conductive material is not mounted on the land 46. That is, in the black circular part, the land 46 is exposed. The pitch between the two lands 46 adjacent to each other can be appropriately adjusted. It is possible to set the pitch to, for example, 60 μm. The diameter of the conductive material and the diameter of the land 46 may be set to, for example, 30 μm.

The material of the land 46 is copper. Therefore, the land 46 has a red metallic luster.

The material of the solder ball includes lead. Therefore, the color of the solder ball is gray. The land 46 and the solder ball have different colors. Therefore, the land 46 and the solder ball may be used as a two-dimensional code.

The land 46 and the conductive material constituting the two-dimensional code are electrically in a floating state. The land 46 is not connected to the wiring pattern inside the circuit board 41.

The information display pattern PT2 includes a plurality of first portions PE in which the conductive material is present and a plurality of second portions PN in which the conductive material is not present. The information display pattern PT2 has a plurality of information display rows PA represented by a combination of the plurality of first portions PE and the plurality of second portions PN. A plurality of information display rows PA are arranged in the X direction and the Y direction intersecting the X direction.

That is, in the present embodiment, the two-dimensional code is formed by the presence or absence of each of the plurality of conductive materials.

A position where the information display pattern PT2 is disposed is not limited to the information display region 47 shown in FIG. 4. Instead of the information display pattern PT1 according to Modification Examples 1 to 3 of the information display region described in the first embodiment, the information display pattern PT2 may be applied.

### Method of Manufacturing NAND Memory

Next, a manufacturing method of the NAND memory 25 having the information display pattern PT2 will be described.

The method of manufacturing the NAND memory 25 of the present embodiment is different from the method of the first embodiment in that step 6 is not performed and that step 7A is performed instead of step 7.

In the following description, the description of the common steps in the steps 1 to 9 in the first embodiment described above will be omitted.

First, the above-described steps 1 to 5 are performed in order. As a result, a large circuit board 50 shown in FIG. 9 is obtained. Next, the following step 7A is performed.

### Step 7A: Disposition of Solder Balls on Large Circuit Board

In step 7A, the collet 160 and the solder base 161 shown in FIGS. 12A and 12B are used. Accordingly, as shown in FIG. 11, the solder balls 145 are disposed on the lands 146, and the solder balls 145 are disposed in the information display regions 147 of each of the plurality of device regions 125. Next, the solder balls 145 are partially removed to correspond to the information display pattern PT2. Thereafter, the above-described steps 8 and 9 are performed.

### Modification Example 1 of Step 7A

A method of disposing the solder balls 145 in the information display region 147 is not limited to the above-described method. As Modification Example 1 of step 7A, a disposition pattern in which the solder balls 145 are disposed may be formed by the inkjet method.

In this case, first, the large circuit board 50 in which the information display region 147 is covered with a solder resist is prepared. Further, an inkjet apparatus capable of discharging an etching solution for removing the solder resist from a discharge head is prepared.

The discharge head of the inkjet device discharges the etching solution to the information display region 147 in accordance with the pattern in which the solder balls 145 are disposed, that is, the information display pattern PT2. At this time, the etching solution partially removes the information display region 147 in accordance with the information display pattern PT2. At this time, a washing step may be performed as necessary. Accordingly, the land 146 according to the information display pattern PT2 is exposed in the information display region 147.

Next, the solder balls 145 are disposed on the lands 146 using the collet 160 in the same manner as in the above-described step 7A. In such a method, it is possible to dispose the solder balls 145 on the lands 146 and to dispose the solder balls 145 in the information display regions 147 of each of the plurality of device regions 125.

### Modification Example 2 of Step 7A

A method of disposing the solder balls 145 in the information display region 147 is not limited to the above-described method. As Modification Example 2 of step 7A, the mask layer may be disposed on the land 146 in which the solder balls 145 are not disposed. The mask layer is a layer for preventing the solder balls from being mounted on a specific land. The mask layer may be referred to as a barrier layer.

In such a method of forming a mask layer, for example, an inkjet device capable of discharging a mask material for forming a mask layer is used. The inkjet device coats the land 146 with the mask material in accordance with the pattern in which the solder balls 145 are not disposed to form a mask layer. In other words, the inkjet device coats the land 146 with the mask material according to the reverse pattern in which the white circular part and the black circular part forming the information display pattern PT2 are inverted with respect to each other, to form the mask layer. Accordingly, the mask layer is disposed in the land 146 where the solder balls 145 are not disposed.

After the mask layer is formed, the same process as in the above-described step 7A is performed. That is, the solder balls 145 are disposed on the lands 146 using the collet 160. In such a method, it is possible to dispose the solder balls 145 on the lands 146 and to dispose the solder balls 145 in the information display regions 147 of each of the plurality of device regions 125.

According to the present embodiment, the information display region 47 can be formed on the second surface 41b of the circuit board 41 configuring the NAND memory 25. In addition, the information display pattern PT2 formed of the conductive material can be formed in the information display region 47. Since it is not necessary to irradiate the surface of the sealing resin portion 43 with the laser light, the semiconductor chip is not damaged. As a result, the thickness of the sealing resin portion 43 can be reduced, and the thickness of the NAND memory 25 can be reduced.

Furthermore, the conductive material configuring the information display pattern PT2 is a solder material, that is, lead. Therefore, when the NAND memory 25 is irradiated with the X-rays, the X-rays do not pass through the portion where the solder balls are disposed, and the X-rays pass through the portion where the conductive material is not disposed. Therefore, the presence or absence of the conductive material, that is, the arrangement pattern of the conductive material can be obtained using X-rays. That is, even after the mounting is completed, the information display pattern PT2 can be read by using X-rays.

In general, a semiconductor package has a plurality of conductive parts bonded to a substrate which is a mounting target of the semiconductor package. In a plan view of the semiconductor package, the conductive portion disposed at the four corners of the plurality of conductive portions is used as a dummy bump.

According to the present embodiment, at least a part of the dummy bump can be used for the information display pattern PT2.

The plurality of conductive members 45 of the NAND memory 25 are members used for inputting and outputting signals of the NAND memory 25. The information display pattern PT2 is a two-dimensional code for the management information of each of the plurality of NAND memory chips 25. Therefore, the input and output terminal of the signal and the two-dimensional code can be formed in the same step.

According to the present embodiment, the same or similar effects as those of the first embodiment described above can be obtained. In particular, since the position of the information display pattern PT2 is not limited to the surface of the sealing resin portion 43, the degree of freedom in the design of the NAND memory 25 can be improved.

### Modification Examples of Second Embodiment

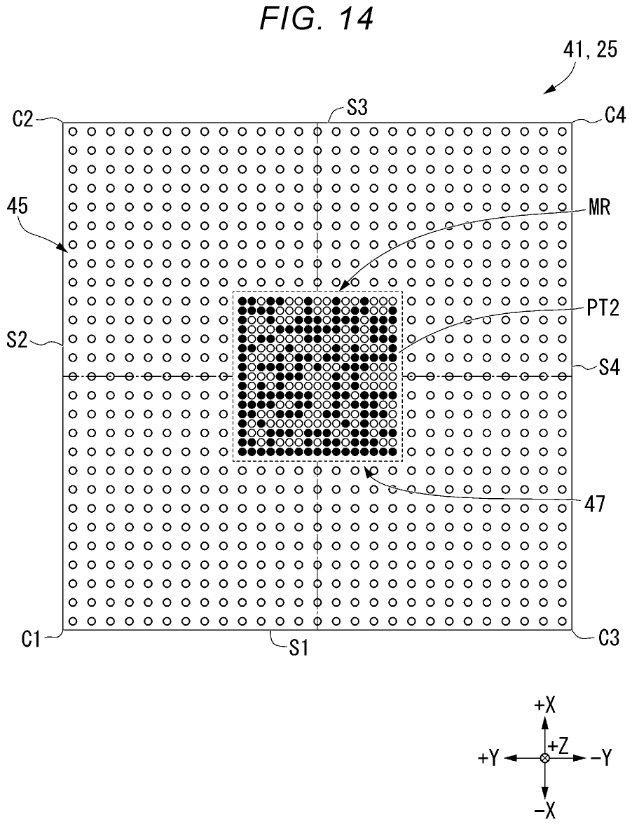

Modification examples according to the second embodiment will be described with reference to FIGS. 14 to 17.

In modification examples of the second embodiment, the same reference numerals are given to the same members as members in the first embodiment and are given to the first embodiment, and the description thereof will be omitted or simplified.

### Modification Example 1

FIG. 14 is a diagram showing Modification Example 1 of the second embodiment. FIG. 14 is a bottom view showing the configuration of the NAND memory 25. FIG. 14 may also be referred to as a plan view of the circuit board 41 as viewed in the +Z direction.

The second surface 41b of the circuit board 41 has a central region MR located at the center in the X direction and the Y direction. The information display region 47 is located in the central region MR. The information display region 47 is provided with an information display pattern PT2.

In the X direction and the Y direction, the pitch of the plurality of first portions PE and the plurality of second portions PN configuring the information display pattern PT2 is ½ of the pitch of the plurality of conductive members 45.

According to Modification Example 1, the same or similar effects as those of the second embodiment described above can be obtained.

### Modification Example 2

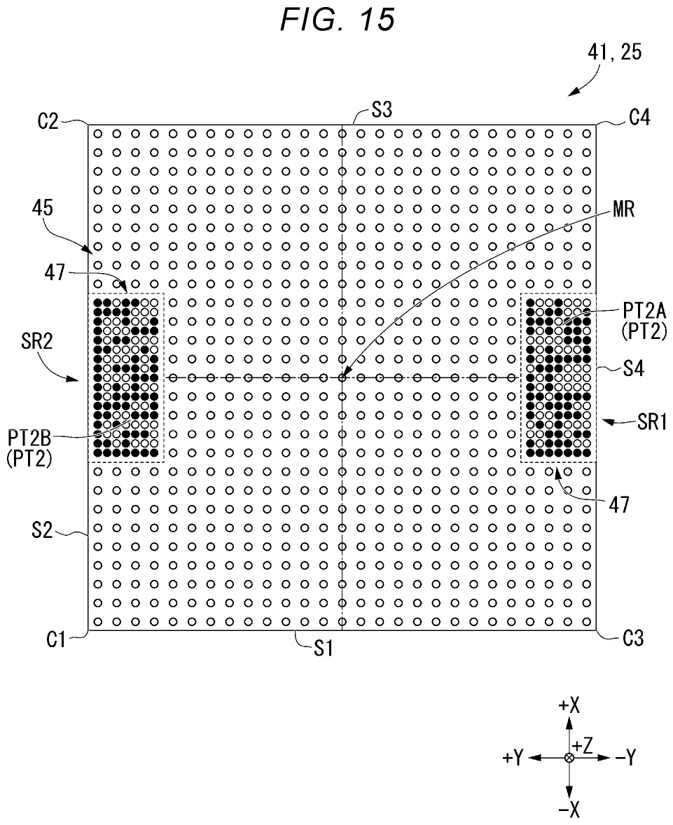

FIG. 15 is a diagram showing Modification Example 2 of the second embodiment. FIG. 15 is a bottom view showing the configuration of the NAND memory 25. FIG. 15 may also be referred to as a plan view of the circuit board 41 as viewed in the +Z direction.

The second surface 41b has the central region MR, a first side region SR1, and a second side region SR2. The central region MR is located at the center in the X direction and the Y direction. The first side region SR1 is located closer to the side portion S4 with respect to the central region MR. The second side region SR2 is located closer to the side portion S2 with respect to the central region MR. The information display region 47 is located in each of the first side region SR1 and the second side region SR2. Each of the first side region SR1 and the second side region SR2 is an example of a “side region”.

The first information display pattern PT2A is formed in the information display region 47 in the first side region SR1. The second information display pattern PT2B is formed in the information display region 47 in the second side region SR2. The two information display patterns, that is, the first information display pattern PT2A and the second information display pattern PT2B form the information display pattern PT2. In other words, the first side region SR1 and the second side region SR2 are disposed at positions symmetric to each other.

In the X direction and the Y direction, the pitch of the plurality of first portions PE and the plurality of second portions PN configuring each of the first information display pattern PT2A and the second information display pattern PT2B is ½ of the pitch of the plurality of conductive members 45.

According to Modification Example 2, the same or similar effects as those of the second embodiment described above can be obtained.

### Modification Example 3

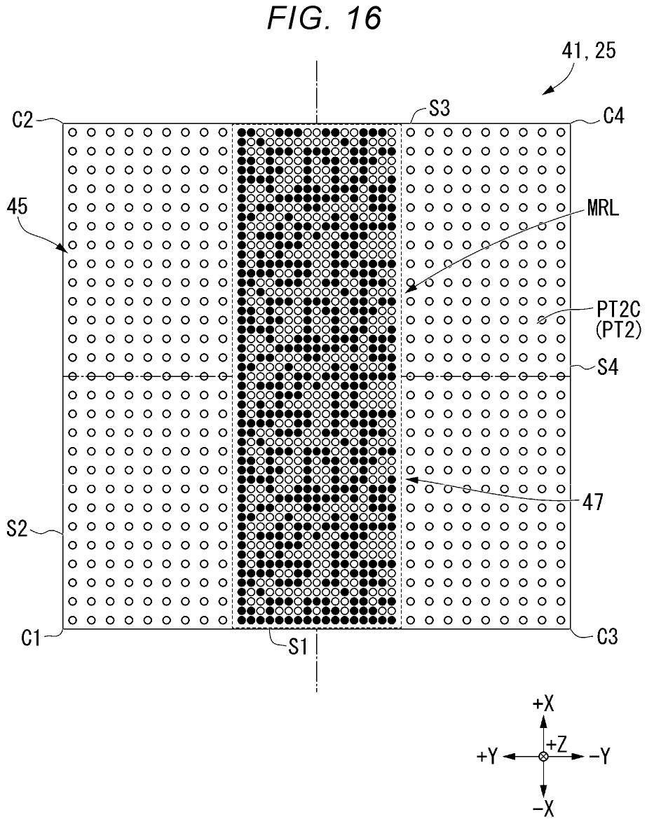

FIG. 16 is a diagram showing Modification Example 3 of the second embodiment. FIG. 16 is a bottom view showing the configuration of the NAND memory 25. FIG. 16 may also be referred to as a plan view of the circuit board 41 as viewed in the +Z direction.

The second surface 41b of the circuit board 41 has a central extension region MRL located at the center in the X direction and the Y direction. The central extension region MRL is an example of a central region. The central extension region MRL extends from the side portion S1 toward the side portion S3. In other words, the shape of the central extension region MRL is a rectangle. The information display region 47 is located in the central extension region MRL. The information display region 47 is provided with an information display pattern PT2.

In the X direction and the Y direction, the pitch of the plurality of first portions PE and the plurality of second portions PN configuring the information display pattern PT2 is ½ of the pitch of the plurality of conductive members 45.

According to Modification Example 3, the same or similar effects as those of the second embodiment described above can be obtained.

### Modification Example 4

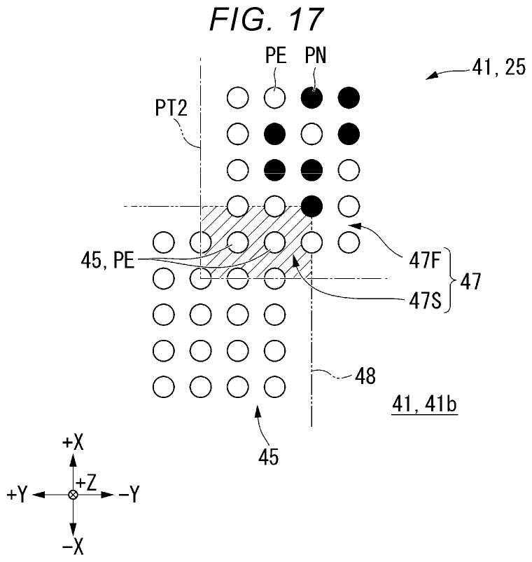

FIG. 17 is a diagram showing Modification Example 4 of the second embodiment. FIG. 17 is a bottom view showing the configuration of the NAND memory 25. FIG. 17 may also be referred to as a plan view of the circuit board 41 as viewed in the +Z direction.

The information display region 47 has a first region 47F and a second region 47S. In FIG. 17, the second region 47S is shown by hatching.

The NAND memory 25 has a terminal region 48. The terminal region 48 is provided on the second surface 41b of the circuit board 41. In the terminal region 48, a plurality of the conductive members 45 are disposed.

The first region 47F is a region provided at a position different from a position of the plurality of conductive members 45. That is, the first region 47F is a region different from the terminal region 48. In other words, the first region 47F is a region located adjacent to the terminal region 48.

The second region 47S is a region provided at a position overlapping the plurality of conductive members 45. That is, the second region 47S is a region that overlaps the terminal region 48.

A part of the plurality of conductive members 45 is a part of the plurality of first portions PE in the second region 47S. In the example shown in FIG. 17, two conductive members 45 correspond to the first portion PE.

In other words, in the second region 47S, the conductive member 45 is the same as the first portion PE configuring the information display pattern PT2.

Further, the conductive member 45 forming a part of the plurality of first portions PE is a heat dissipation part that dissipates heat generated in the NAND memory 25. In other words, the conductive member 45 forming a part of the plurality of first portion PE is a thermal ball.

According to Modification Example 4, the same or similar effects as those of the second embodiment described above can be obtained.

Further, a part of the plurality of conductive members 45 is a part of the plurality of first portions PE in the second region 47S. Therefore, the conductive member 45 and the information display pattern PT2 can be made common in the second region 47S.

The conductive member 45 forming a part of the plurality of first portions PE is a heat dissipation part. Therefore, the heat generated in the NAND memory 25 can be dissipated.

In Modification Example 4, the two conductive members 45 correspond to the first portion PE. The number of common portions shared by the conductive member 45 and the first portion PE is not limited to two. The number of the common portions may be one or may be three or more. In Modification Example 4, the common portion is located in the corner region forming the terminal region 48, but the common portion may be located in the linear region forming the terminal region 48. The linear region is, for example, a part of a region extending in the X direction or the Y direction.

### Modification Examples of First Embodiment and Second Embodiment

In the above-described embodiment, the structure of the NAND memory 25 having the information display region has been described. The structure applied to the NAND memory 25 may be applied to the DRAM 26 or the controller 22.

In addition, in the above-described embodiment, a case where the information display pattern is a two-dimensional code has been described. The above-described embodiment is not limited to the two-dimensional code. The information display pattern may be a one-dimensional code, that is, a barcode.

In Modification Examples 1 to 3 of the second embodiment, the configuration in which the information display pattern PT2 is formed in the information display region 47 has been described. The information display pattern PT1 may be formed in the information display regions 47 of Modification Examples 1 to 3.

According to at least one embodiment described above, the semiconductor storage device includes a circuit board, an electronic component, a plurality of conductive members, and an information display region. The circuit board has a first surface and a second surface on a side opposite to the first surface. The electronic component is mounted on the first surface of the circuit board. The plurality of conductive members are disposed on the second surface of the circuit board. The plurality of conductive members are electrically connected to the circuit board. The plurality of conductive members are formed of a conductive material. The information display region is provided on the second surface of the circuit board. At least a part of the information display region is provided at a position different from a position of the plurality of conductive members. The information display region has an information display pattern formed of the same conductive material as the coating material or the conductive material. As a result, it is possible to provide a semiconductor storage device capable of improving the degree of freedom in design.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor storage device comprising:
a circuit board having a first surface and a second surface opposite to each other;
an electronic component disposed on the first surface of the circuit board;
a plurality of conductive members disposed on the second surface of the circuit board and electrically coupled to the circuit board, wherein the conductive members each include a conductive material; and
an information display region provided on the second surface of the circuit board, wherein
the information display region includes an information display pattern formed of a coating material or the conductive material of the conductive members.

2. The semiconductor storage device according to claim 1, wherein
the second surface is parallel to a first direction intersecting a thickness direction of the circuit board and to a second direction intersecting each of the thickness direction and the first direction,
the circuit board has a plurality of corner portions,
the second surface has a central region that is located at a center in the first direction and the second direction, and a corner region that is located closer to one corner portion among the plurality of corner portions than the central region, and
the information display region is located in the corner region.

3. The semiconductor storage device according to claim 1, wherein
the second surface is parallel to a first direction intersecting a thickness direction of the circuit board and to a second direction intersecting each of the thickness direction and the first direction,
the second surface has a central region located at a center in the first direction and the second direction, and
the information display region is located in the central region.

4. The semiconductor storage device according to claim 1, wherein
the second surface is parallel to a first direction intersecting a thickness direction of the circuit board and to a second direction intersecting each of the thickness direction and the first direction,
the circuit board has a plurality of corner portions and a side portion located between two corner portions of the plurality of corner portions adjacent to each other,
the second surface has a central region that is located at a center in the first direction and the second direction and a side region that is located closer to the side portion than the central region, and
the information display region is located in the side region.

5. The semiconductor storage device according to claim 1, wherein
the information display pattern includes a plurality of first portions having the coating material and a plurality of second portions free of the coating material.

6. The semiconductor storage device according to claim 5, wherein
the information display pattern has a plurality of information display rows corresponding to a combination of the plurality of first portions and the plurality of second portions, and
the plurality of information display rows are arranged in a first direction and a second direction intersecting the first direction.

7. The semiconductor storage device according to claim 1, wherein
the information display pattern includes a plurality of first portions having the conductive material and a plurality of second portions not having the conductive material.

8. The semiconductor storage device according to claim 7, wherein
the information display pattern has a plurality of information display rows corresponding to a combination of the plurality of first portions and the plurality of second portions, and
the plurality of information display rows are arranged in a first direction and a second direction intersecting the first direction.

9. The semiconductor storage device according to claim 8, wherein
the information display region includes a first region provided at a position different from a position of the plurality of conductive members and a second region provided at a position overlapped with the plurality of conductive members, and
one or more of the plurality of conductive members are included by a part of the plurality of first portions in the second region.

10. The semiconductor storage device according to claim 9, wherein
the one or more conductive members are configured to be a heat dissipation part.

11. The semiconductor storage device according to claim 1, wherein
the plurality of conductive members are electrical connection terminals exposed from the second surface of the circuit board.

12. A semiconductor storage device comprising:
a circuit board having a first surface and a second surface opposite to each other;
an electronic component disposed on the first surface of the circuit board;
a plurality of conductive members disposed on the second surface of the circuit board and electrically coupled to the circuit board, wherein the conductive members each include a conductive material; and
an information display region provided on the second surface of the circuit board, wherein
the information display region includes a plurality of first portions having a coating material or the conductive material of the conductive members, and a plurality of second portions free of the coating material or the conductive material of the conductive members.

13. The semiconductor storage device according to claim 12, wherein
the second surface is parallel to a first direction intersecting a thickness direction of the circuit board and to a second direction intersecting each of the thickness direction and the first direction,
the circuit board has a plurality of corner portions,
the second surface has a central region that is located at a center in the first direction and the second direction, and a corner region that is located closer to one corner portion among the plurality of corner portions than the central region, and
the information display region is located in the corner region.

14. The semiconductor storage device according to claim 12, wherein
the second surface is parallel to a first direction intersecting a thickness direction of the circuit board and to a second direction intersecting each of the thickness direction and the first direction,
the second surface has a central region located at a center in the first direction and the second direction, and
the information display region is located in the central region.

15. The semiconductor storage device according to claim 12, wherein
the second surface is parallel to a first direction intersecting a thickness direction of the circuit board and to a second direction intersecting each of the thickness direction and the first direction,
the circuit board has a plurality of corner portions and a side portion located between two corner portions of the plurality of corner portions adjacent to each other,
the second surface has a central region that is located at a center in the first direction and the second direction and a side region that is located closer to the side portion than the central region, and
the information display region is located in the side region.
